(19) United States
(12) Patent Application Publication
(10) Pub. No.: US 2023/0237231 A1
(43) Pub. Date: Jul. 27, 2023

(54) Modular Compilation Flows for a Programmable Logic Device

(71) Applicant: Intel Corporation, Santa Clara, CA (US)

(72) Inventors: Byron Sinclair, Toronto (CA); Michael Kinsner, Halifax (CA); Gabriel Quan, Toronto (CA); Victor Tzi-on Zhang, Toronto (CA); Mahesh A. Iyer, Fremont, CA (US); Chengping Liang, Toronto (CA); Deshanand P. Singh, Toronto (CA)

(21) Appl. No.: 18/191,785

(22) Filed: Mar. 28, 2023

(51) Int. Cl. G06F 30/347; G06F 30/31

(52) U.S. Cl. CPC G06F 30/347; G06F 30/31

(57) ABSTRACT

Systems or methods of the present disclosure may provide an electronic device that includes memory storing instructions; and a processor, that when executing the instructions, is to receive a design for a programmable fabric of an integrated circuit device. The instructions are also to cause the processor to cause compilation of the design into a configuration during a compilation window. The instructions further are to cause the processor to determine at least some routing for the configuration outside of the compilation window.

### BACKGROUND

The present disclosure relates generally to programmable logic devices. More particularly, the present disclosure relates to reducing compile time for programmable logic devices such as high-capacity field programmable gate arrays (FPGAs).

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Programmable logic devices, a class of integrated circuits, may be programmed to perform a wide variety of operations. In certain instances, compiling the programmable logic device with a high-level design (HLD) may take a long period of time, such as multiple hours or multiple days. The long compilation time may block market traction. For example, the long compilation time may increase both development cost and development time, thereby reducing adoption of programmable logic devices. Moreover, the programmable logic devices may be fine-grained for compiling register transfer level (RTL) based designs. As such, a design may be decomposed down into millions of primitives to be compiled into the fine-grained programmable device, thereby increasing the compile time. Indeed, compilation time for fine-grained programmable logic devices may be computationally intensive, resource intensive, and cost intensive due to the fine-grained nature of the programmable logic device. Furthermore, routing may be implemented for compiled flows for the programmable logic device using soft-routing-implemented in a fabric of the programmable logic device and/or using overlays/virtual fabrics. For instance, the routing may be implemented using post-compile configurable multiplexers and/or may be implemented in look-up tables (LUTs) instead of using routing fabric multiplexers already present in the fabric. In other words, this configuration of multiplexers may use more storage, logic, configuration time, and/or compile time to implement these multiplexers.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device, in accordance with an embodiment of the present disclosure;

FIG. 2 is a block diagram of the integrated circuit device of FIG. 1, in accordance with an embodiment of the present disclosure;

FIG. 3 is a block diagram of programmable fabric of the integrated circuit device of FIG. 1, in accordance with an embodiment of the present disclosure;

FIG. 4 is a block diagram of a portion of the integrated circuit device of FIG. 1 that modularizes regions to include a processing element and an adjacent switch, in accordance with an embodiment of the present disclosure;

FIG. 5 is a flow chart of a process that may be implanted using design software, a compiler, and/or a host, in accordance with an embodiment of the present disclosure;

FIG. 6 is a block diagram of data flows of regions, in accordance with an embodiment of the present disclosure;

FIG. 7 illustrates a routing addition process that may be compiled with no external routing in a region, in accordance with an embodiment of the present disclosure;

FIG. 8 illustrates a routing modification process that may modify from a basic set or default set of routing for a region, in accordance with an embodiment of the present disclosure;

FIG. 9 is a flowchart of a process that may be used in implementing routing in a programmable fabric, in accordance with an embodiment of the present disclosure;

FIG. 10 is a flow diagram of a process using a logic and local routing layer for implementing a function in one or more processing elements (PEs) in programmable fabric of the integrated circuit device of FIG. 1, in accordance with an embodiment of the present disclosure;

FIG. 11 is a flow diagram of a process that utilizes one more partitions/routing layers that includes an individual route, in accordance with an embodiment of the present disclosure;

FIG. 12 is a flow diagram of a process that may be performed using the techniques of FIG. 10 and/or FIG. 11, in accordance with an embodiment; and

FIG. 13 is a block diagram of a data processing system including the integrated circuity device of FIG. 1, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

The present disclosure describes systems and techniques that relate to various modular routing implementations to decrease compile time for high-capacity integrated circuitry, such as high-capacity field programmable gate arrays (FPGAs) or other programmable logic devices. In particular, the embodiments described herein are directed to modular circuitry regions that include programmable elements and an adjacent switch and pre-compiling possible routing configurations that may be used in implementing a data flow graph of coarse-grained operations. By pre-compiling the routing configurations, a high-level design (HLD) program may be compiled with reduced compile times. By enabling the pre-compiled (or post-compilation-window compiled) routing configurations, routing may be performed via a routing network of the programmable logic device without consuming excess area and/or performance overhead. To this end, a library may include one or more personas for realizing the design on the FPGA. The design may be decomposed into one or more personas. In certain instances, the personas may be compiled into the regions of the FPGA and executed to realize the design. In another instance, the personas may be pre-compiled (or post-compiled) into the regions and routing between the regions may realize the design. For example, the personas may be pre-compiled (or post-compiled) for each location, operation, and data type. By partially reconfiguring the regions, compile time may be decreased. For example, the compile time (e.g., from code to FPGA hardware execution) for the FPGA using regions may be a few seconds to a few minutes. Further, the FPGA may include network-on-chips (NOCs) to improve off-chip memory transport from the partial reconfiguration and enable spatial decoupling of logic resources, thereby reducing the compile time. Indeed, reducing compilation time may increase adoption of FPGAs by reducing cost and resources used to bring the FPGA to market.

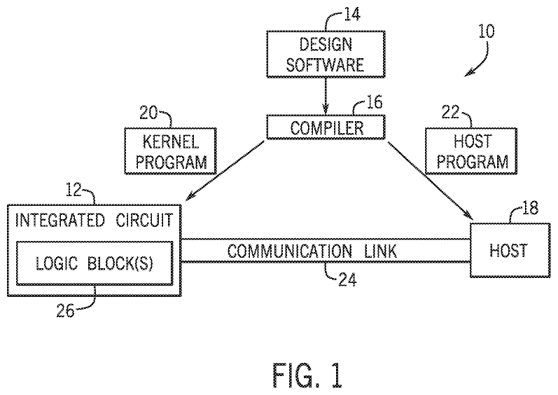

With the foregoing in mind, FIG. 1 illustrates a block diagram of a system 10 that may implement one or more functionalities. For example, a designer may desire to implement functionality, such as the operations of this disclosure, on an integrated circuit device 12 (e.g., a programmable logic device, such as a field programmable gate array (FPGA) or an application specific integrated circuit (ASIC)). In some cases, the designer may specify a high-level program to be implemented, such as an OPENCL® program, which may enable the designer to more efficiently and easily provide programming instructions to configure a set of programmable logic cells for the integrated circuit device 12 without specific knowledge of low-level hardware description languages (e.g., Verilog or VHDL). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

The designer may implement high-level designs using design software 14, such as a version of INTEL® QUARTUS® by INTEL CORPORATION. The design software 14 may use a compiler 16 to convert the high-level program into a lower-level description. In some embodiments, the compiler 16 and the design software 14 may be packaged into a single software application. The compiler 16 may provide machine-readable instructions representative of the high-level program to a host 18 and the integrated circuit device 12. The host 18 may receive a host program 22 which may be implemented by the kernel programs 20. To implement the host program 22, the host 18 may communicate instructions from the host program 22 to the integrated circuit device 12 via a communications link 24, which may be, for example, direct memory access (DMA) communications or peripheral component interconnect express (PCIe) communications. In some embodiments, the kernel programs 20 and the host 18 may enable configuration of a logic block 26 on the integrated circuit device 12. The logic block 26 may include circuitry and/or other logic elements and may be configured to implement arithmetic operations, such as addition and multiplication.

The design software 14 may be used to generate and/or to specify a low-level program, such as the low-level hardware description languages described above. For example, the design software 14 may be used to map a workload to one or more routing resources of the integrated circuit device 12 based on a timing, a wire usage, a logic utilization, and/or a routability. In another example, the design software 14 may be used to route first data to a portion of the integrated circuit device 12 and route second data, power, and clock signals to a second portion of the integrated circuit device 12. Further, in some embodiments, the system 10 may be implemented without a separate host program 22. Moreover, in some embodiments, the techniques described herein may be implemented in circuitry as a non-programmable circuit design. Thus, embodiments described herein are intended to be illustrative and not limiting.

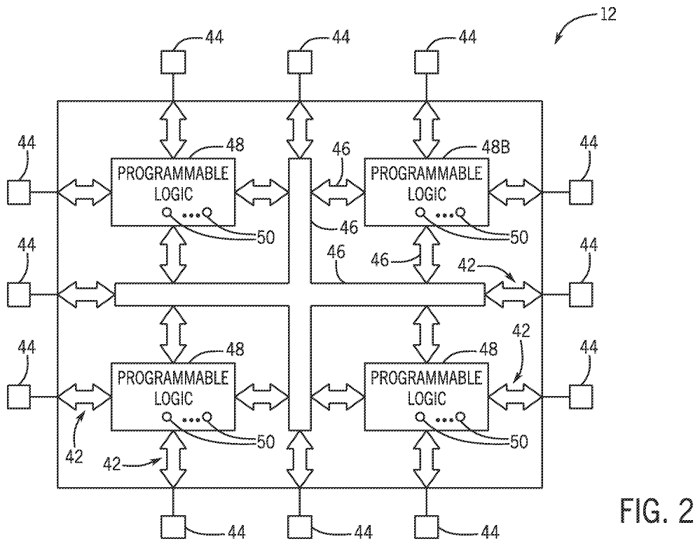

Turning now to a more detailed discussion of the integrated circuit device 12, FIG. 2 is a block diagram of an example of the integrated circuit device 12 as a programmable logic device, such as a field-programmable gate array (FPGA). Further, it should be understood that the integrated circuit device 12 may be any other suitable type of programmable logic device (e.g., a structured ASIC such as eASICTM by Intel Corporation and/or application-specific standard product). The integrated circuit device 12 may have input/output circuitry 42 for driving signals off the device and for receiving signals from other devices via input/output pins 44. Interconnection resources 46, such as global and local vertical and horizontal conductive lines and buses, and/or configuration resources (e.g., hardwired couplings, logical couplings not implemented by user logic), may be used to route signals on integrated circuit device 12. Additionally, interconnection resources 46 may include fixed interconnects (conductive lines) and programmable interconnects (i.e., programmable connections between respective fixed interconnects). For example, the interconnection resources 46 may be used to route signals, such as clock or data signals, through the integrated circuit device 12. Additionally or alternatively, the interconnection resources 46 may be used to route power (e.g., voltage) through the integrated circuit device 12. Programmable logic 48 may include combinational and sequential logic circuitry. For example, programmable logic 48 may include look-up tables, registers, and multiplexers. In various embodiments, the programmable logic 48 may be configured to perform a custom logic function. The programmable interconnects associated with interconnection resources may be considered to be a part of programmable logic 48.

Programmable logic devices, such as the integrated circuit device 12, may include programmable elements 50 with the programmable logic 48. In some embodiments, at least some of the programmable elements 50 may be grouped into logic array blocks (LABs). As discussed above, a designer (e.g., a customer) may (re)program (e.g., (re)configure) the programmable logic 48 to perform one or more desired functions. By way of example, some programmable logic devices may be programmed or reprogrammed by configuring programmable elements 50 using mask programming arrangements, which is performed during semiconductor manufacturing. Other programmable logic devices are configured after semiconductor fabrication operations have been completed, such as by using electrical programming or laser programming to program programmable elements 50. In general, programmable elements 50 may be based on any suitable programmable technology, such as fuses, antifuses, electrically programmable read-only-memory technology, random-access memory cells, mask-programmed elements, and so forth.

Many programmable logic devices are electrically programmed. With electrical programming arrangements, the programmable elements 50 may be formed from one or more memory cells. For example, during programming, configuration data is loaded into the memory cells using input/output pins 44 and input/output circuitry 42. In one embodiment, the memory cells may be implemented as random-access-memory (RAM) cells. The use of memory cells based on RAM technology as described herein is intended to be only one example. Further, since these RAM cells are loaded with configuration data during programming, they are sometimes referred to as configuration RAM cells (CRAM). These memory cells may each provide a corresponding static control output signal that controls the state of an associated logic component in programmable logic 48. For instance, in some embodiments, the output signals may be applied to the gates of metal-oxide-semiconductor (MOS) transistors within the programmable logic 48.

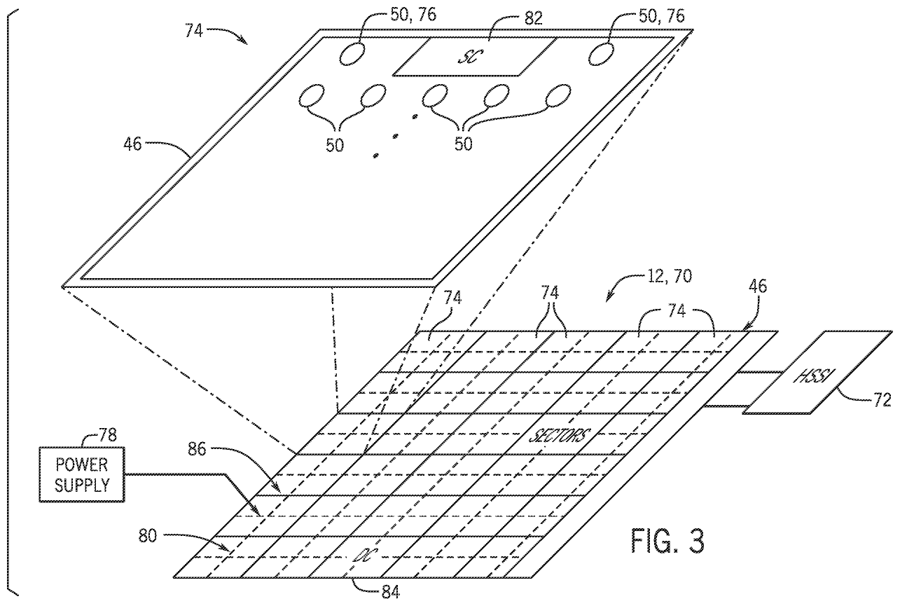

The integrated circuit device 12 may include any programmable logic device such as a field programmable gate array (FPGA) 70, as shown in FIG. 3. For the purposes of this example, the FPGA 70 is referred to as a FPGA, though it should be understood that the device may be any suitable type of programmable logic device (e.g., an application-specific integrated circuit and/or application-specific standard product). In one example, the FPGA 70 is a sectorized FPGA of the type described in U.S. Patent Publication No. 2016/0049941, “Programmable Circuit Having Multiple Sectors,” which is incorporated by reference in its entirety for all purposes. The FPGA 70 may be formed on a single plane. Additionally or alternatively, the FPGA 70 may be a three-dimensional FPGA having a base die and a fabric die of the type described in U.S. Pat. No. 10,833,679, “Multi-Purpose Interface for Configuration Data and User Fabric Data,” which is incorporated by reference in its entirety for all purposes.

In the example of FIG. 3, the FPGA 70 may include a transceiver 72 that may include and/or use input/output circuitry, such as input/output circuitry 42 in FIG. 2, for driving signals off the FPGA 70 and for receiving signals from other devices. Interconnection resources 46 may be used to route signals, such as clock or data signals, through the FPGA 70. The FPGA 70 is sectorized, meaning that programmable logic resources may be distributed through a number of discrete programmable logic sectors 74. Programmable logic sectors 74 may include a number of programmable logic elements 50 having operations defined by configuration memory 76 (e.g., CRAM). A power supply 78 may provide a source of voltage (e.g., supply voltage) and current to a power distribution network (PDN) 80 that distributes electrical power to the various components of the FPGA 70. Operating the circuitry of the FPGA 70 causes power to be drawn from the power distribution network 80.

There may be any suitable number of programmable logic sectors 74 on the FPGA 70. Indeed, while 29 programmable logic sectors 74 are shown here, it should be appreciated that more or fewer may appear in an actual implementation (e.g., in some cases, on the order of 50, 100, 500, 1000, 5000, 10,000, 50,000 or 100,000 sectors or more). Programmable logic sectors 74 may include a sector controller (SC) 82 that controls operation of the programmable logic sector 74. Sector controllers 82 may be in communication with a device controller (DC) 84.

Sector controllers 82 may accept commands and data from the device controller 84 and may read data from and write data into its configuration memory 76 based on control signals from the device controller 84. In addition to these operations, the sector controller 82 may be augmented with numerous additional capabilities. For example, such capabilities may include locally sequencing reads and writes to implement error detection and correction on the configuration memory 76 and sequencing test control signals to effect various test modes.

The sector controllers 82 and the device controller 84 may be implemented as state machines and/or processors. For example, operations of the sector controllers 82 or the device controller 84 may be implemented as a separate routine in a memory containing a control program. This control program memory may be fixed in a read-only memory (ROM) or stored in a writable memory, such as random-access memory (RAM). The ROM may have a size larger than would be used to store only one copy of each routine. This may allow routines to have multiple variants depending on “modes” the local controller may be placed into. When the control program memory is implemented as RAM, the RAM may be written with new routines to implement new operations and functionality into the programmable logic sectors 74. This may provide usable extensibility in an efficient and easily understood way. This may be useful because new commands could bring about large amounts of local activity within the sector at the expense of only a small amount of communication between the device controller 84 and the sector controllers 82.

Sector controllers 82 thus may communicate with the device controller 84, which may coordinate the operations of the sector controllers 82 and convey commands initiated from outside the FPGA 70. To support this communication, the interconnection resources 46 may act as a network between the device controller 84 and sector controllers 82. The interconnection resources 46 may support a wide variety of signals between the device controller 84 and sector controllers 82. In one example, these signals may be transmitted as communication packets.

The use of configuration memory 76 based on RAM technology as described herein is intended to be only one example. Moreover, configuration memory 76 may be distributed (e.g., as RAM cells) throughout the various programmable logic sectors 74 of the FPGA 70. The configuration memory 76 may provide a corresponding static control output signal that controls the state of an associated programmable logic element 50 or programmable component of the interconnection resources 46. The output signals of the configuration memory 76 may be applied to the gates of metal-oxide-semiconductor (MOS) transistors that control the states of the programmable logic elements 50 or programmable components of the interconnection resources 46.

The programmable elements 50 of the FPGA 40 may also include some signal metals (e.g., communication wires) to transfer a signal. In an embodiment, the programmable logic sectors 74 may be provided in the form of vertical routing channels (e.g., interconnects formed along a y-axis of the FPGA 70) and horizontal routing channels (e.g., interconnects formed along an x-axis of the FPGA 70), and each routing channel may include at least one track to route at least one communication wire. If desired, communication wires may be shorter than the entire length of the routing channel. That is, the communication wire may be shorter than the first die area or the second die area. A length L wire may span L routing channels. As such, a length of four wires in a horizontal routing channel may be referred to as “H4” wires, whereas a length of four wires in a vertical routing channel may be referred to as “V4” wires.

As discussed above, some embodiments of the programmable logic fabric may be configured using indirect configuration techniques. For example, an external host device may communicate configuration data packets to configuration management hardware of the FPGA 70. The data packets may be communicated internally using data paths and specific firmware, which are generally customized for communicating the configuration data packets and may be based on particular host device drivers (e.g., for compatibility). Customization may further be associated with specific device tape outs, often resulting in high costs for the specific tape outs and/or reduced salability of the FPGA 70.

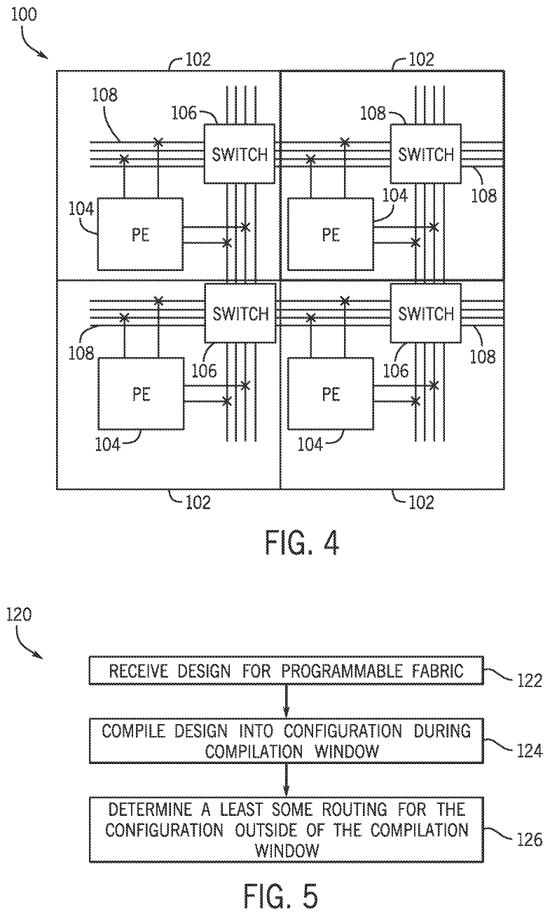

FIG. 4 is a block diagram of a portion 100 of the integrated circuit device 12 that modularizes regions 102 to include a processing element (PE) 104 and an adjacent switch 106 along with related routes 108. These regions 102 (or regional bitstreams) may be pre-compiled (or post-compiled) that will be assembled with other regions 102 to implement a design generated and/or compiled using the design software 14 and/or the compiler 16. The regions 102 may include any logical region of the integrated circuit device. These regions can be implemented/stitched together using partial reconfiguration or another suitable flow.

For example, the design may include high-level programming language, such as an array language, Python, C#, C++, and the like. The design may also include circuitry and/or other logic elements and may be configured to implement arithmetic operations, such as addition, subtraction, multiplication, and so on. Additionally or alternatively, the design may map a workload to one or more routing resources based on a timing, a wire usage, a logic usage, and/or a routability. To enable implementation of such routability, the region(s) 102 may be pre-compiled (or post-compiled) with multiple or even all possible routing configurations for the adjacent switch 106. By using such implementations rather than an overlay or a LUT-enabled switch, the routing network of the programmable fabric may be used directly, providing a smaller area/performance overhead to provide the functionality than using software-implemented multiplexers or configuration bits. A coarse-grained place and routing may be used to manifest a specific data flow graph that defines a PR routing configuration to be selected for execution. Instead, in some embodiments, the routes 108 may be wires. In some embodiments, the routes may include hardware-implemented multiplexers.

The design may be decomposed into a compiler data flow graph (e.g., bounded combinatorial explosions) that may be compiled into the regions 102. For example, LLVM IR may be used to decompose the design into a compiler data flow graph. The design may be decomposed to define a bounded set of primitive operators, define a standard data type and width, define a memory access mode and/or memory models, control flow graphs, one or more personas, and the like. That is, high level bounding may be used to generate a data flow.

As previously noted, compiling a user design for the programmable logic device may take a relatively long period of time, such as multiple hours or multiple days. The long compilation time may increase both development cost and development time, thereby reducing adoption of programmable logic devices and/or drastically slow trouble shooting of designs. As these designs may be decomposed down into numerous (e.g., millions) of primitives to be compiled into the fine-grained programmable device, thereby increasing the compile time. Indeed, compilation time for fine-grained programmable logic devices may be computationally intensive, resource intensive, and cost intensive due to the fine-grained nature of the programmable logic device. By moving compilation of some of the routing configurations outside of the compilation window, this compilation window may be reduced in size.

FIG. 5 is a flow chart diagram of a process 120 that may be implemented using the design software 14, the compiler 16, and/or the host 18. The design software 14, the compiler 16, and/or the host 18 receives a design for a programmable fabric of the integrated circuit device 12 (block 122). Receiving the design may include receiving inputs via the design software to generate a new design and/or may include receiving a stored configuration or bitstream from memory or another electronic device with or without changes. The compiler 16 may compile the design into a configuration during a compilation window (block 124). Additionally or alternatively, the design software 14 and/or the host 18 may cause the compiler to compile the design. The design software 14, the compiler 16, and/or the host 18 may determine at least some of the routing 108 outside of the compilation window (block 126). Determining the at least some routing may include compiling and/or setting the at least some routing before or after the compilation window. For instance, pre-compiled route configurations may be incorporated and/or default routes (e.g., pre-compiled routes or no routes) may be used during the compilation to be replaced at a later time using engineering change orders, bitstream perturbations, or other post-compilation changes.

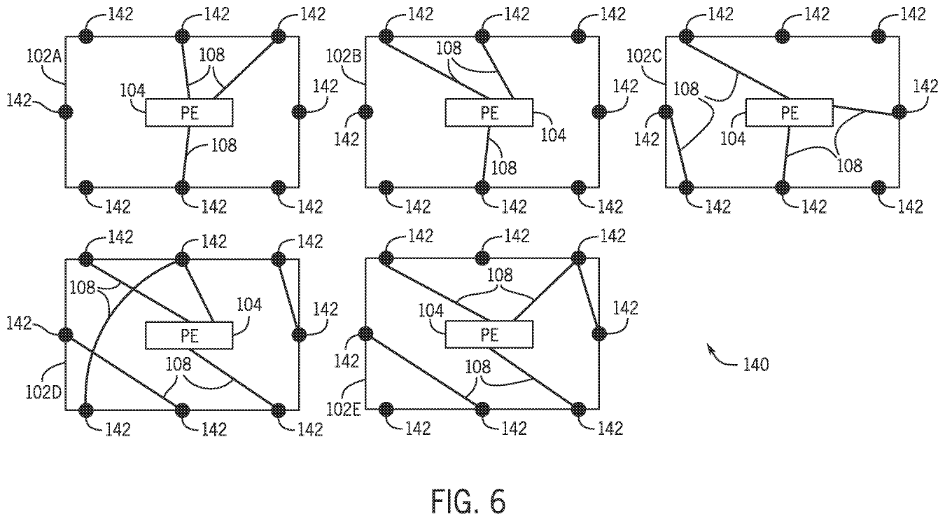

The data flow may include any suitable number of nodes implemented using a region to realize the design on the integrated circuit device 12. For example, FIG. 6 shows data flows 140 of regions 102A, 102B, 102C, 102D, and 102E (collectively referred to as regions 102). As illustrated, the regions 102 each include multiple nodes 142 that may be used to route data between processing elements (PEs) 104 that are used to perform various operations, such as storing data in memory, loading data from memory, arithmetic operations, and the like. The individual regions 102A, 102B, 102C, 102D, and 102E may correspond to different options (e.g., routing configurations in a library) that may be available for a region 102. Moreover, the nodes 142 may be set or standardized to align between regions without further tweaking. Additionally or alternatively, the nodes 142 may be substantially aligned within a distance that may be corrected using tweaks within a region 102 to enable the routes 108 within the corresponding regions 102 to be aligned for connectivity.

The nodes 142 may correspond to a modular connection point or inter-block connectivity port that may be used to connect routes 108 across the blocks. Additionally or alternatively, the nodes 142 may correspond to multiple connection points or ports for connection to a corresponding PE 104 within the corresponding region or even different connection points or ports for connection inside of a corresponding PE 104. In other words, the routing 108 may correspond to inter-region connectivity between coarse-grained regions 102 to provide connectivity between those regions 102, intra-region connectivity between PEs 104 in a region 102 (when there is more than one PE 104 in a region 102), intra-PE connectivity within the logic circuitry of a PE 104 to establish performance of a function within the PE 104, or a combination of two or more connectivity types. Any of these type of routes 108 may be used in the techniques described above and/or below.

One difficulty in pre-compiling all possible routing configurations for a region is that a combinatorial explosion may occur due to a multitude of different route configurations. Thus, some approaches may be used to reduce the sheer potential massive numbers of possible configurations.

To reduce the number of possible configurations, a global network size may be reduced to reduce the number of overall configurations. For instance, direct sneak paths may be made available between adjacent PEs 104. Furthermore, the addition of these direct sneak paths may reduce restrictions of locations of PEs 104 by enabling any type of PE 104 to be placed in multiple locations (or even anywhere) that would not have been available without the direct sneak paths. The sneak paths may be added before, during, and/or after compilation. Additionally, the sneak paths may utilize carry chain connections between PEs 104 and/or may be separate from the carry chains.

Additionally or alternatively, a basic set of connections (e.g., default versions of the routes 108) may be set and pre-compiled. An engineering change order (an ECO) or other similar flows may be used to re-route at least one of the routes 108. An ECO-based change differs from changing the design (e.g., RTL) in that an ECO requires more knowledge of how to change the integrated circuit device 12. However, the ECO or similar changes may be made to make such changes without the overhead costs and performance needed to implement an RTL-design-based change by using hardware routing circuitry (e.g., multiplexers and wires) that may not be configurable using design changes alone. An ECO may be used to change and/or add sneak pathing. In some embodiments, the re-routing from the default routes may be performed online if they can be completed fast enough. However, if the re-routing may take too long for an online re-route, the re-routing may be performed offline with or without a restart of the integrated circuit device 12. Furthermore, in some embodiments, the default or basic routing configurations may be placed, routed, and pre-compiled, then a subset of the routing 108 may be compiled and/or ECO'd differently than the pre-compiled routes 108.

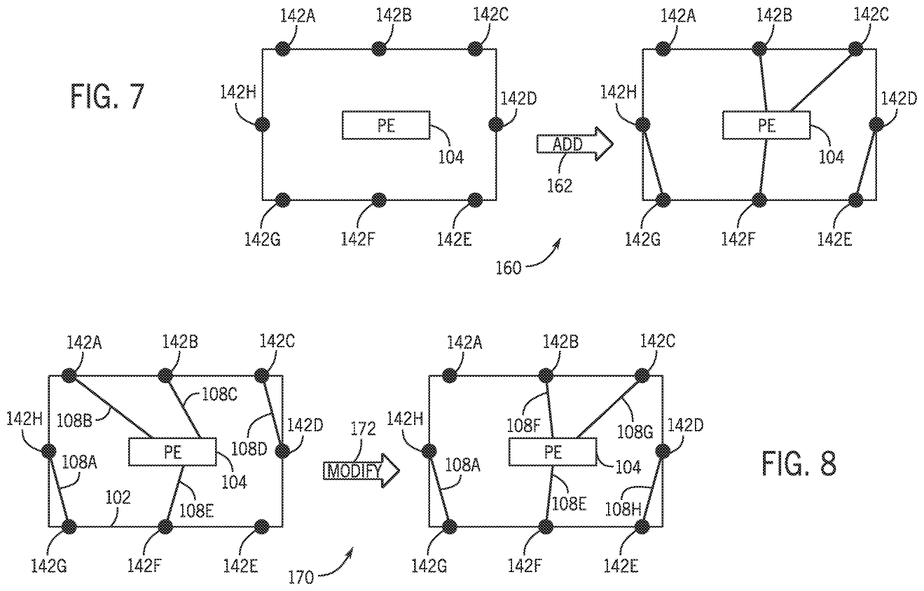

For instance, FIG. 7 shows a routing addition process 160 that may be compiled with no external routing in a region 102. Specifically, after compilation, the nodes 142A, 142B, 142C, 142D, 142E, 142F, 142G, and 142H (collectively referred to as nodes 142) are not connected to the PE 104 or each other during or before compilation. Instead, the internal routing inside the PE 104 (and/or between PEs 104 where there are multiple PEs 104 in the region 102) may be routed. Alternatively, all routing internal and external may be left out of the pre-compilation and added later using an ECO or other similar mechanism. After the addition 162 (e.g., ECO), external routes (e.g., routes 108) may be routed through nodes 142B, 142C, and 142F to the PE 104. The addition 162 also adds routes 108 between nodes 142H and 142G and between nodes 142D and 142E.

FIG. 8 shows a routing modification process 170 that may be compiled with a basic set or default set of routing for a region 102 (e.g., some routes are pre-compiled and/or are not compiled with other parts of the design). The basic set or default set may be determined or selected from a library. Additionally or alternatively, the basic set or default set may be a routing configuration that was previously used by a user. For instance, the used configuration may be stored to the library for future use after compilation for use by a previous design by the user at a previous time. The region 102 includes nodes 142A, 142B, 142C, 142D, 142E, 142F, 142G, and 142H (collectively referred to as nodes 142). The pre-compiled routing in the region 102 includes a route 108A connecting the nodes 142G and 142H together, a route 108B connecting the PE 104 to the node 142A together, a route 108C connecting the PE 104 to the node 142B, a route 108D connecting the nodes 142C and 142D together, and a route 108E connecting the PE 104 to the node 142F. However, this pre-compiled default route configuration may be unsuitable for final usage. Instead, a post-compilation change (e.g., ECO or the like) may be made as a modification 172 to the routes 108. Specifically, the nodes 142A and 142B may be disconnected from the PE 104 by removing routes 108B and 108C. Similarly, the modification 172 may include disconnecting the nodes 142C and 142D from each other by removing the route 108D. The modification 172 may include adding a route 108F to connect the node 142B to the PE 104, adding a route 108G to connect the node 142C to the PE 104, and adding a route 108H to connect the nodes 142D and 142E together. In some embodiments, the addition 162 and/or the modification 172 may be performed together sequentially or simultaneously.

Furthermore, the addition 162 and/or modification 172 may be constrained by various rules. For instance, some default routes may be prioritized and/or locked from being changed or removed. Furthermore, how the routes are changed may prioritize minimizing the amount of changes. By prioritizing using routes that are already pre-compiled over routes yet to be compiled may lead to fewer pre-compiled routes may be stored in the library and may lead to fewer route additions/modifications needing to be compiled within the compilation window. For instance, in some embodiments, the route 108C may remain after the modification 172 instead of replacing it with the route 108F. Moreover, in some embodiments, the total number of changes may have a maximum or minimum threshold that are to be satisfied before performing changes on the routing.

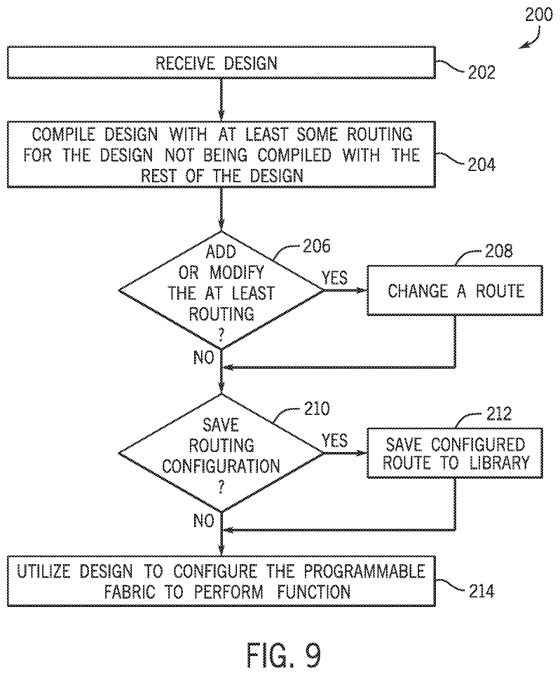

FIG. 9 is a flow chart of a process 200 that may be used in implementing routing in a programmable fabric. The process 200 may be implemented using the design software 14, the compiler 16, and/or the host 18. The design software 14, the compiler 16, and/or the host 18 receives a design for a programmable fabric of the integrated circuit device 12 (block 202). Receiving the design may include receiving inputs via the design software to generate a new design and/or may include receiving a stored configuration or bitstream from memory or another electronic device with or without changes. The compiler 16 may compile the design with at least some routing for the design not being compiled with the rest of the design (block 204). For example, the at least some routing may be pre-compiled or changed/added/compiled after the reset of the design is compiled. Additionally or alternatively, the design software 14 and/or the host 18 may cause the compiler 16 to compile the rest of the design. The design software 14, the compiler 16, and/or the host 18 may compile the at least some of the routing 108 before and/or after compiling the rest of the design. As such, the design software 14, the compiler 16, and/or the host 18 may perform compilation and/or placement of routing before and/or after the compilation of the rest of user design. For instance, pre-compiled route configurations may be incorporated and/or default routes (e.g., pre-compiled routes or no routes) may be used during the compilation. The design software 14, the compiler 16, and/or the host 18 may determine whether additions or modifications are to be performed on the at least some routing (block 206). If so, the design software 14, the compiler 16, and/or the host 18 may cause a route to change (block 208). For instance, the design software 14, the compiler 16, and/or the host 18 may determine that a default route may be replaced using engineering change orders, bitstream perturbations, or other similar post-compilation changes. Otherwise, the default route(s) may continue to be used.

The design software 14, the compiler 16, and/or the host 18 may then determine whether a routing configuration is to be saved (block 210). For instance, the design may be marked as to be saved using a radial button in a user interface of the design software 14 indicating that any changes from the default route may be saved for later use. The design software 14, the compiler 16, and/or the host 18 may then save the route configuration to the library (block 212). Saving the route configuration to the library may include saving the route configuration as the new default overwriting a current default route or may include supplementing the current default route with an additional option.

Regardless of whether the route configuration is saved or not, the design software 14, the compiler 16, and/or the host 18 may utilize the design to configure the integrated circuit device 12 to load the design into a programmable fabric of the integrated circuit device 12 to perform one or more functions utilizing the design and route configuration (block 214).

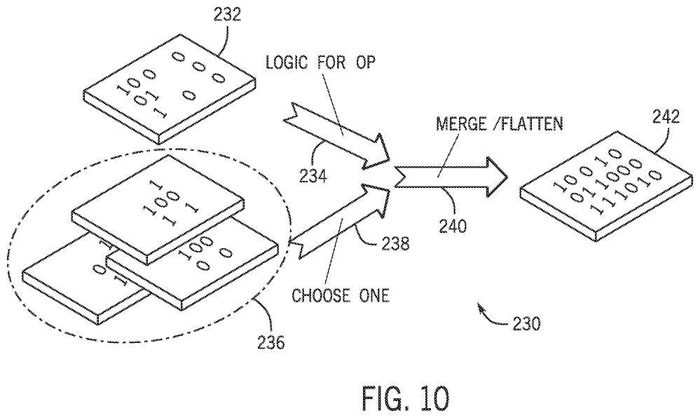

As previously noted, the design may include local routing, such as intra-region routing or intra-PE routing where external routing out of the regions 102 may be separate. FIG. 10 is a flow diagram of a process 230 using a logic and local routing layer 232 (e.g., design) that includes the logic 234 implementation for implementing a function in one or more PEs 104 in the programmable fabric of the integrated circuit device 12. The logic and local routing layer 232 may also include the local routing with the corresponding region(s) 102 and/or PE(s) 104. A library 236 of routing layers may include inter-region routing options and/or boundary signals that provide pre-compiled configurations that may be incorporated in the integrated circuit device 12 to implement the design. For example, a picker box may provide selectable options in the design software to choose 238 routing configurations and a corresponding routing layer from the library 236. Additionally or alternatively, the design software 14 may compare the design to functions and/or routing in the library 236 to select the options that are the best fit. The inter-region routing and boundary signal routing may be pre-compiled. Thus, the longer inter-region routing and boundary signal routing options may be independently compiled between module interface ports and other ports or internal logic, creating a library of routing layer bitstreams for regions 102.

The bitstreams of the compiled logic and local routing layer 232 and the selected routing layer may then be merged and/or flattened 240 to generate a compiled region bitstream 242 used to load the configuration (logic, internal routing, and external routing) into the programmable fabric of the programmable logic device 12. In other words, during compilation, the shorter internal routes and operation logic are separated from the external routing and boundary signal routing to reduce time to compile the design.

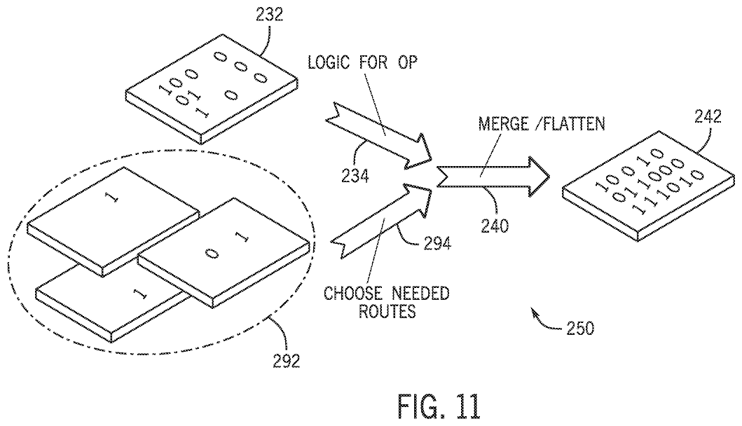

In addition to or alternative to routing layers with multiple routes configured, individual routing paths may be expressed as partitions of the routing layers (e.g., individual routing layers). For instance, FIG. 11 is a flow diagram of a process 250 that utilizes one or more partitions/routing layers that includes an individual route. The process 250 is similar to the process 230 except that the library 252 contains partitions/individual routing layers and choosing the routes 254 includes forming a composite/merge of bit values of the different partitions/routing layers to form a composite routing layer. The composite routing layer may be like the selected routing layer from the library 236 that contains multiple routes with remaining portions of the process 250 following the same steps as those of process 230 after compositing the individual external routes/boundary signal routing. In some embodiments, some routes may be mutually exclusive using constraints that keep multiple routes from being assigned the same resources.

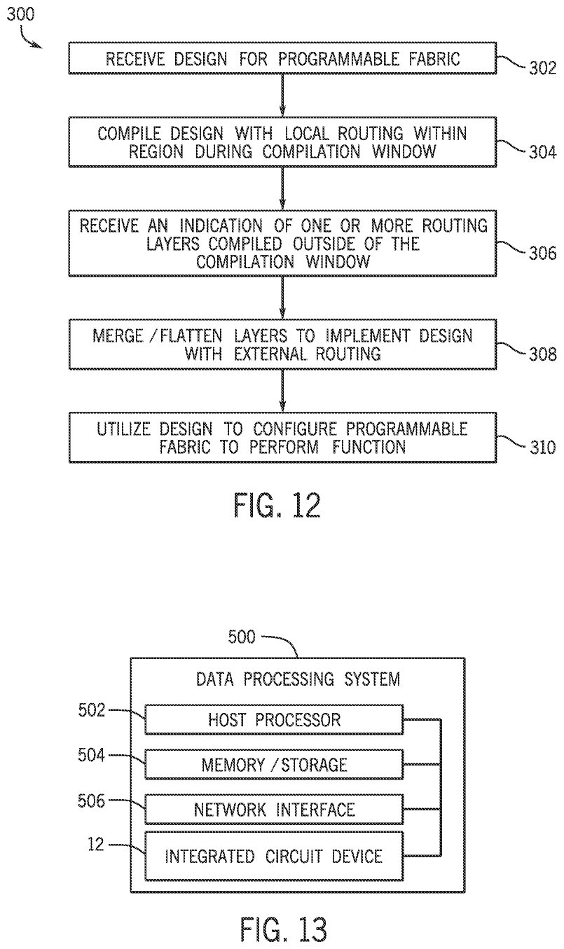

FIG. 12 is a flow diagram of a process 300 that may be performed using the techniques in FIGS. 10 and/or 11. The process 300 may be implemented using the design software 14, the compiler 16, the host 18, and/or any other suitable electronic device. The design software 14, the compiler 16, and/or the host 18 receives a design for a programmable fabric of the integrated circuit device 12 (block 302). As previously noted, receiving the design may include receiving inputs via the design software to generate a new design and/or may include receiving a stored configuration or bitstream from memory or another electronic device with or without changes. The compiler 16 may compile the design with local routing into a configuration during a compilation window (block 304). Additionally or alternatively, the design software 14 and/or the host 18 may cause the compiler to compile the design. The design software 14, the compiler 16, and/or the host 18 may receive an indication of one or more routing layers that have been compiled outside of the compilation window (block 306). As previously noted, these one or more routing layers may be pre-compiled (or post-compiled) relative to the compilation of the logic layer with the local routing. Also, the indication may include a determined best fit from multiple possible routing layers or partitions to meet the design. Furthermore, the indication may include receiving a selection of a route in the design software 14. Moreover, in some embodiments, the design software 14 may recommend a best fit route layer/partitions/layers and receive the indication as confirmation of the best fit or a selection of alternative routing. Additionally, the one or more routing layers may include a routing layer that defines multiple routes, a partition of a routing configuration that defines only a portion of possible routes (e.g., a single route). The design software 14, the compiler 16, and/or the host 18 may then merge/flatten the compiled design with local routing and the one or more routing layers to implement a design with external routing (block 308). The merging/flattening may be performed in a single step or in multiple steps. For instance, if there are multiple routing layers/partitions selected, the bit values for the individual routes may be composited into a single routing layer that is then merged with the compiled logic layer with local routing to generate the bitstream for the region 102. Alternatively or additionally, the multiple routing layers/partitions and the compiled logic layer with local routing to generate the bitstream for the region 102 may be combined together at one time. The design software 14, the compiler 16, and/or the host 18 may then utilize the design to configure the programmable fabric of the integrated circuit device 12 to perform a function corresponding to the design (block 310).

In some embodiments, timing closure may be performed as part of the ahead of time pre-compilation. For instance, the pre-compiled regions 102 may have a maximum frequency (Fmax) and/or other timing information from their previous compilations. This information may be used when compiling the design. For instance, all routing paths may have registers at the boundary to ensure that the same Fmax is achieved in all regions 102. Additionally or alternatively, the design software 14, the compiler 16, and/or the host 18 may analyze the worst-case paths between registers in any combination of regions 102 and calculate the Fmax as part of the pre-compilation. Additionally or alternatively, a relatively high Fmax may be achieved through static or dynamic (e.g., via ECO) insertion of registers/buffers along critical paths determined from heuristics and/or coarse-grained timing analysis. Thus, ECOs may be used to make small perturbations to critical paths to increase the Fmax.

In some embodiments, the number of routes that may be implemented may be constrained. To reduce the number of routes needed to perform the foregoing techniques, a route may be fractured into smaller width buses based on the common data types to use the routes. For instance, if a route is a default 32 bits unlikely to carry more than 8 bits, the route may be fractured into a number of (e.g., 4) fractured buses.

Although the flow diagrams illustrate the steps in certain sequences, it should be understood that the steps may be performed in any suitable order and certain steps may be carried out simultaneously, where appropriate. For example, the blocks 304 and 306 may illustrated as block 304 being performed before block 306, but some embodiments may perform block 306 before block 304. Further, certain steps or portions of the flow diagrams may be performed by separate systems or devices.

Bearing the foregoing in mind, the integrated circuit device 12 may be a component included in a data processing system, such as a data processing system 500, shown in FIG. 13. The data processing system 500 may include the integrated circuit device 12 (e.g., a programmable logic device), a host processor 504 (e.g., a processor), memory and/or storage circuitry 506, and a network interface 508. The data processing system 500 may include more or fewer components (e.g., electronic display, user interface structures, application specific integrated circuits (ASICs)). Moreover, any of the circuit components depicted in FIG. 13 may include integrated circuits (e.g., integrated circuit device 12). The host processor 504 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 506 may include random access memory (RAM), read-only memory (ROM), one or more hard drives, flash memory, or the like. The memory and/or storage circuitry 506 may hold data to be processed by the data processing system 500. In some cases, the memory and/or storage circuitry 506 may also store configuration programs (bitstreams) for programming the integrated circuit device 12. The network interface 508 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

In one example, the data processing system 500 may be part of a data center that processes a variety of different requests. For instance, the data processing system 500 may receive a data processing request via the network interface 508 to perform encryption, decryption, machine learning, video processing, voice recognition, image recognition, data compression, database search ranking, bioinformatics, network security pattern identification, spatial navigation, digital signal processing, or some other specialized task.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]. . . ” or “step for [perform]ing [a function]. . . ”, it is intended that such elements are to be interpreted under 35 U.S.C. 112(f). However, for any claims containing elements designated in any other manner, it is intended that such elements are not to be interpreted under 35 U.S.C. 112(f).

### Example Embodiments

EXAMPLE EMBODIMENT 1. An electronic device, comprising: memory storing instructions; and a processor, that when executing the instructions, is to: receive a design for a programmable fabric of an integrated circuit device; cause compilation of the design into a configuration during a compilation window; and determine at least some routing for the configuration outside of the compilation window.

EXAMPLE EMBODIMENT 2. The electronic device of example embodiment 1, wherein determining the at least some routing for the configuration comprises compiling the at least some routing before compiling the design in the compilation window.

EXAMPLE EMBODIMENT 3. The electronic device of example embodiment 1, wherein the at least some routing comprises external routing connecting a region with circuitry outside of the region.

EXAMPLE EMBODIMENT 4. The electronic device of example embodiment 2, wherein causing compilation of the design during the compilation window comprises compiling intra-region routes.

EXAMPLE EMBODIMENT 5. The electronic device of example embodiment 4, wherein intra-region routes comprise routes between processing elements of the programmable fabric or within processing elements of the programmable fabric.

EXAMPLE EMBODIMENT 6. The electronic device of example embodiment 1, wherein the at least some routing comprises native multiplexers of the programmable fabric.

EXAMPLE EMBODIMENT 7. The electronic device of example embodiment 1, wherein determining the at least some routing comprises adding or modifying routing after the compilation window.

EXAMPLE EMBODIMENT 8. The electronic device of example embodiment 7, wherein adding or modifying routing comprises using an engineering change order.

EXAMPLE EMBODIMENT 9. A method, comprising: receiving a design for a programmable fabric of an integrated circuit device; compiling the design with at least some routing for an implementation of the design not being compiled with the rest of the design; determining to add or modify a route of the at least some routing; changing the route; and utilizing the design to configure the programmable fabric to perform a function using the changed route.

EXAMPLE EMBODIMENT 10. The method of example embodiment 9, wherein the at least some routing for an implementation of the design comprises default pre-configured routes.

EXAMPLE EMBODIMENT 11. The method of example embodiment 9, wherein the at least some routing comprises no external routes extending outside of a region until after compilation of the design.

EXAMPLE EMBODIMENT 12. The method of example embodiment 9, wherein changing the route includes removing the route, adding a route, replacing the route, or combination thereof.

EXAMPLE EMBODIMENT 13. The method of example embodiment 9, comprising saving the changed route to a library.

EXAMPLE EMBODIMENT 14. The method of example embodiment 13, comprising receiving a selection of the at least some routing as pre-compiled routes previously saved to the library.

EXAMPLE EMBODIMENT 15. An electronic device, comprising: memory storing instructions and a plurality of routing layers each indicating one or more pre-compiled routes available for use in a design; and a processor, that when executing the instructions, is to: receive the design for a programmable fabric of an integrated circuit device; compile the design with local routing within a region during a compilation window; receive an indication of one or more of the plurality of routing layers; merge the one or more of the plurality of routing layers with the design with local routing to generate a configuration bitstream; and utilize the configuration bitstream to configure the programmable fabric of the integrated circuit device.

EXAMPLE EMBODIMENT 16. The electronic device of example embodiment 15, wherein the instructions are part of design software stored in the memory and implemented by the processor.

EXAMPLE EMBODIMENT 17. The electronic device of example embodiment 15, wherein a routing layer of plurality of routing layers comprises a single route for the region.

EXAMPLE EMBODIMENT 18. The electronic device of example embodiment 17, wherein the instructions, when executed, are to cause the processor to merge the one or more of the plurality of routing layers into a composite routing layer before merging the one or more of the plurality of routing layers with the design with local routing.

EXAMPLE EMBODIMENT 19. The electronic device of example embodiment 15, wherein a routing layer of the plurality of routing layers comprises multiple routes indicated in the routing layer.

EXAMPLE EMBODIMENT 20. The electronic device of example embodiment 15, wherein the local routing comprises between processing elements of the region or within a processing element of the region, and the pre-compiled routes extend to a boundary of the region.

What is claimed is:

1. An electronic device, comprising:
memory storing instructions; and
a processor, that when executing the instructions, is to:
receive a design for a programmable fabric of an integrated circuit device;
cause compilation of the design into a configuration during a compilation window; and
determine at least some routing for the configuration outside of the compilation window.

2. The electronic device of claim 1, wherein determining the at least some routing for the configuration comprises compiling the at least some routing before compiling the design in the compilation window.

3. The electronic device of claim 1, wherein the at least some routing comprises external routing connecting a region with circuitry outside of the region.

4. The electronic device of claim 1, wherein causing compilation of the design during the compilation window comprises compiling intra-region routes.

5. The electronic device of claim 4, wherein the intra-region routes comprise routes between processing elements of the programmable fabric or within processing elements of the programmable fabric.

6. The electronic device of claim 1, wherein the at least some routing comprises native multiplexers of the programmable fabric.

7. The electronic device of claim 1, wherein determining the at least some routing comprises adding or modifying routing after the compilation window.

8. The electronic device of claim 7, wherein adding or modifying routing comprises using an engineering change order.

9. A method, comprising:
receiving a design for a programmable fabric of an integrated circuit device;
compiling the design with at least some routing for an implementation of the design not being compiled with the rest of the design;
determining to add or modify a route of the at least some routing;
changing the route; and
utilizing the design to configure the programmable fabric to perform a function using the changed route.

10. The method of claim 9, wherein the at least some routing for the implementation of the design comprises default pre-configured routes.

11. The method of claim 9, wherein the at least some routing comprises no external routes extending outside of a region until after compilation of the design.

12. The method of claim 9, wherein changing the route includes removing the route, adding an additional route, replacing the route, or combination thereof.

13. The method of claim 9, comprising saving the changed route to a library.

14. The method of claim 13, wherein determining whether to add or modify the route comprises prioritizing using routes that are pre-compiled over routes that are yet to be compiled.

15. An electronic device, comprising:
memory storing instructions and a plurality of routing layers each indicating one or more pre-compiled routes available for use in a design; and
a processor, that when executing the instructions, is to:
receive the design for a programmable fabric of an integrated circuit device;
compile the design with local routing within a region during a compilation window;
receive an indication of one or more of the plurality of routing layers;
merge the one or more of the plurality of routing layers with the design with local routing to generate a configuration bitstream; and
utilize the configuration bitstream to configure the programmable fabric of the integrated circuit device.

16. The electronic device of claim 15, wherein the instructions are part of design software stored in the memory and implemented by the processor.

17. The electronic device of claim 15, wherein a routing layer of plurality of routing layers comprises a single route for the region.

18. The electronic device of claim 17, wherein the instructions, when executed, are to cause the processor to merge the one or more of the plurality of routing layers into a composite routing layer before merging the one or more of the plurality of routing layers with the design with local routing.

19. The electronic device of claim 15, wherein a routing layer of the plurality of routing layers comprises multiple routes indicated in the routing layer.

20. The electronic device of claim 15, wherein the local routing comprises between processing elements of the region or within a processing element of the region, and the pre-compiled routes extend to a boundary of the region.
